(19) United States
(12) Patent Application Publication
(10) Pub. No.: US 2005/0274958 A1
(43) Pub. Date: Dec. 15, 2005

(54) Buffer layer of light emitting semiconducting device

(76) Inventors: Ting-Kai Huang, Taipei (TW); Chi-Shen Lee, Taipei (TW); Hung-Chang Lai, Chang-Hwa City (TW)

Correspondence Address: SUPREME PATENT SERVICES, POST OFFICE BOX 2339, SARATOGA, CA, 95070, US

(21) Appl. No.: 10/867,369

(22) Filed: Jun. 12, 2004

(51) Int. Cl. H01L 27/15

(52) U.S. Cl. 257/79; 257/103

(57) ABSTRACT

Disclosed is a buffer layer within a light emitting semiconducting device. The buffer layer comprises a plurality of metallic nitride layers sequentially formed on top of a sapphire substrate. In a fabrication process of the buffer layer, an Aluminum nitride layer is first formed on the sapphire substrate by a reaction with ammonia and the sapphire substrate's surface under a high temperature. Then on top of the Aluminum nitride layer, a plurality of metallic nitride layers are formed by reactions between ammonia and metallic organic materials under a high temperature. A buffer layer constructed as such has better quality and fewer defects.

### FIELD OF THE INVENTION

The present invention relates to a buffer layer within a light emitting semiconducting device, and more particularly, to a multi-layer buffer layer within a light emitting semiconducting device that can enhance the device light emitting efficiency.

### BACKGROUND OF THE INVENTION

Gallium nitride (GaN) is a well-known material and has been widely used in semiconducting devices. In recent years, it has been more and more popular in using materials such as Gallium nitride (GaN), Indium Gallium nitride (InGaN), Indium nitride (InN), Aluminum Gallium nitride (AlGaN) and Aluminum Indium Nitride (AlInN) to fabricate blue light emitting semiconducting devices. These devices usually use a sapphire substrate. During a fabrication process, a buffer layer is first formed on the substrate. Then a semiconducting layer of N-type Gallium nitride (GaN), Indium Gallium nitride (InGaN) or Aluminum Gallium nitride (AlGaN) is formed on the buffer layer.

FIG. 1 is a schematic, cross-sectional diagram of a light emitting semiconducting device 10 according to a prior art. As shown in FIG. 1, a buffer layer 102 is formed on a sapphire substrate 101. The buffer layer 102 is a mono-crystalline metallic nitride layer formed by a heteroepitaxy process using materials such as Gallium nitride (GaN), Aluminum nitride (AlN), Indium nitride (InN), Indium Gallium nitride (InGaN), Aluminum Indium Nitride (AliN), or Aluminum Indium Gallium Nitride (AlInGaN) on the sapphire substrate 101. More specifically, the process applies metallic organic (MO) vapors such as Trimethylgallium (TMG), Trimethylaluminum (TMA), Trimethylindium (TMI), ammonia (NH₃), etc. simultaneously on the substrate 101 in a Metal Organic Chemical Vapor Deposition (MOCVD) reaction chamber and increases a temperature to form the buffer layer 102. Then on top of the buffer layer 102, a lower confinement layer 103, a light emitting layer 104, an upper confinement layer 105 and a contact layer 106 is formed sequentially from bottom up. In addition, electrodes 107 and 108 are formed on the contact layer 106 and the lower confinement layer 103 respectively.

However in the foregoing process, Gallium nitride and sapphire have lattice mismatches and significant differences in coefficients of thermal expansion. In addition, Gallium nitride is a hexagonal crystal. A lumpy surface is caused by small hexagonal hillocks grown on the sapphire substrate under the high temperature. It is therefore very difficult to form high quality Gallium nitride films with smooth surfaces. The light emitting semiconducting device thereby has an inferior light emitting efficiency.

Accordingly, the present invention is directed to obviate the foregoing problems and provides a high quality buffer layer with fewer defects and a smooth surface, so that a light emitting efficiency of a light emitting semiconducting device can be effectively improved.

### SUMMARY OF THE INVENTION

An objective of the present invention is to provide a high quality buffer layer with fewer defects and a smooth surface, so that a light emitting efficiency of a light emitting semiconducting device can be effectively improved.

Another objective of the present invention is to provide a buffer layer within a light emitting semiconducting device with a high electron mobility, so that the device's light emitting efficiency can be effectively improved.

Another objective of the present invention is to provide a buffer layer within a light emitting semiconducting device so that the device's operating voltage can be reduced.

In order to achieve the foregoing objectives, a buffer layer within a light emitting semiconducting device according to the present invention comprises a plurality of metallic nitride layers sequentially formed on a substrate. More particularly, an Aluminum nitride (AlN) is first formed on the substrate under a high temperature. Then a plurality of metallic nitride layers is grown on the Aluminum nitride (AlN) layer under a high temperature.

The Aluminum nitride (AlN) layer is formed by a nitridation reaction between ammonia (NH₃) and Aluminum molecules of the sapphire substrate (Al₂O₃) under a high temperature. The process can be describe by a chemical equation as follows:
2Al₂O₃+4NH3->4AlN+6H₂+3O₂
On the other hand the plurality of metallic nitride layers can be formed by reactions between metallic organic materials and ammonia under a high temperature.

The plurality of metallic nitride layers is formed by stacking metallic nitrides such as, but not limited to, Indium nitride (InN), Indium Gallium nitride (InGaN), Aluminum Gallium nitride (AlGaN), Gallium nitride (GaN), etc. Each metallic nitride layer has a thickness between 0.1-50 nanometer (nm).

In a stacking sequence of the plurality of metallic nitride layers, an Indium nitride (InN) layer is first formed on the aforementioned Aluminum nitride (AlN) layer. Then on top of the Indium nitride (InN) layer, layers of Indium Gallium nitride (InGaN), Aluminum Gallium nitride (AlGaN) and Gallium nitride (GaN) are sequentially formed. In another stacking sequence, layers of Indium nitride (InN), Indium Gallium nitride (InGaN), Indium nitride (InN), Aluminum Gallium nitride (AlGaN) and Gallium nitride (GaN) are sequentially formed. Or, in another stacking sequence, layers of Indium nitride (InN), Indium Gallium nitride (InGaN) and Gallium nitride (GaN) are sequentially formed. Or, in another stacking sequence, layers of Indium nitride (InN), Indium Gallium nitride (InGaN), Indium nitride (InN) and Gallium nitride (GaN) are sequentially formed. These stacking sequences of metallic nitrides, as embodiments of the present invention, are exemplary and explanatory are, and are not intended to provide any restriction to the present invention as claimed.

The aforementioned Indium Gallium nitride (InGaN) can be expressed with a chemical formula InₓGa₁₋ₓN, wherein 0≦x≦1. And the aforementioned Aluminum Gallium nitride can be expressed with a chemical formula Al_{y}Ga_{1-y}N, wherein 0≦y≦1.

Further explanation to the present invention will be given through references to the following embodiments of the present invention. The embodiments of the present invention are exemplary and explanatory, and are not intended to provide further restriction to the present invention as disclosed above. To those skilled in the related arts, various modifications and variations can be made to embodiments of the present invention without departing from the spirit and scope of the present invention as claimed.

### BRIEF DESCRIPTION OF THE DRAWINGS

FIG. 1 is a schematic, cross-sectional diagram of a light emitting semiconducting device according to a prior art.

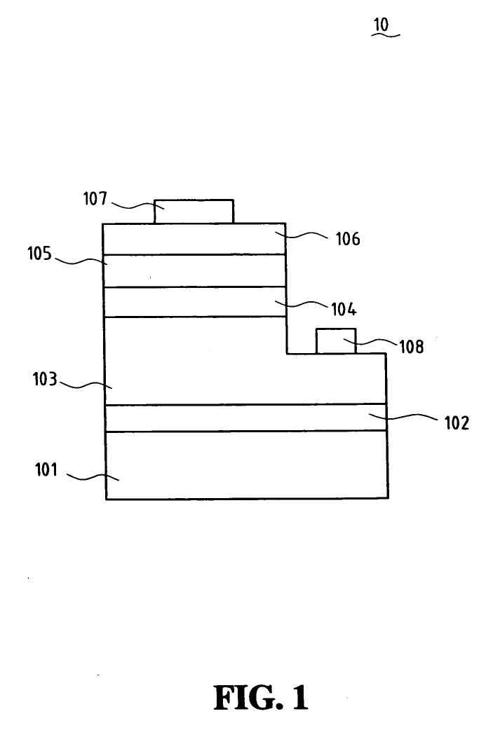

FIG. 2 is a schematic, cross-sectional diagram showing a buffer layer of a light emitting semiconducting device according to a first embodiment of the present invention.

FIG. 3 is a schematic, cross-sectional diagram showing a buffer layer of a light emitting semiconducting device according to a second embodiment of the present invention.

FIG. 4 is a schematic, cross-sectional diagram showing a buffer layer of a light emitting semiconducting device according to a third embodiment of the present invention.

FIG. 5 is a schematic, cross-sectional diagram showing a buffer layer of a light emitting semiconducting device according to a fourth embodiment of the present invention.

FIG. 6 is a schematic diagram showing an Aluminum nitride layer formed on a sapphire substrate.

FIG. 7 is an analytical graph showing data obtained from an analysis of a light emitting semiconducting device with a buffer layer according to the present invention under a Secondary Ion Mass Spectrometer (SIMS).

FIG. 8 is a luminance-current graph showing data obtained from testing light emitting semiconducting devices according to a prior art (shown with the legend ▴) and the present invention (shown with the legend ▪) respectively.

FIG. 9 is a voltage-current graph showing data obtained from testing light emitting semiconducting devices according to a prior art (shown with the legend ▴) and the present invention (shown with the legend ▪) respectively.

### DETAILED DESCRIPTION OF THE PREFERRED EMBODIMENT

To make the objectives, characteristics, and features of the present invention more understandable to those skilled in the related arts, further explanation along with the accompanying drawings is given in the following.

A buffer layer according to the present invention within a light emitting semiconducting device comprises an Aluminum nitride (AlN) layer and a plurality of metallic nitride layers formed on top of the Aluminum nitride layer. As a sapphire substrate for the buffer layer has Aluminum oxide (Al₂O₃) as a major constituent, the Aluminum nitride layer is formed by a nitridation reaction between ammonia (NH₃) and Aluminum molecules of the sapphire substrate under a high temperature. The plurality of the metallic nitride layers is formed by reactions between ammonia and metallic organic materials under a high temperature.

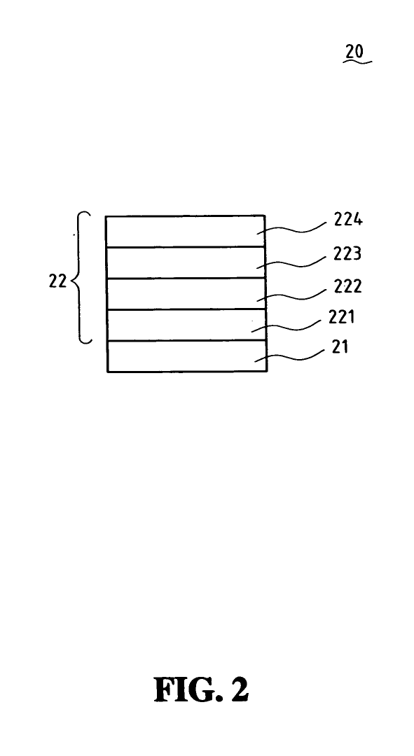

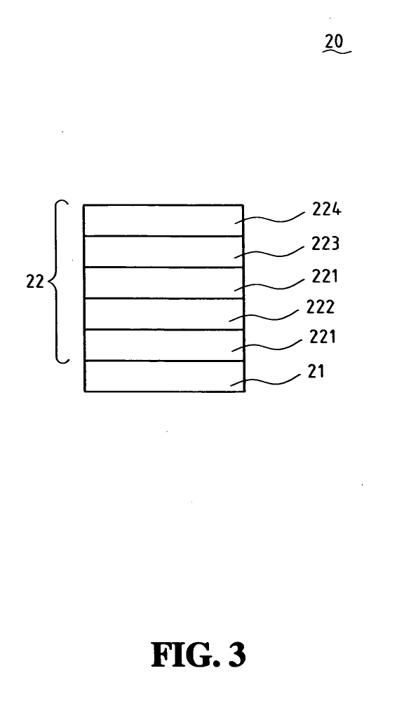

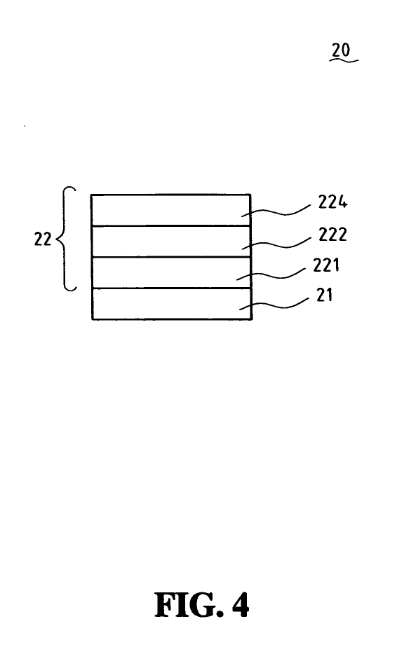

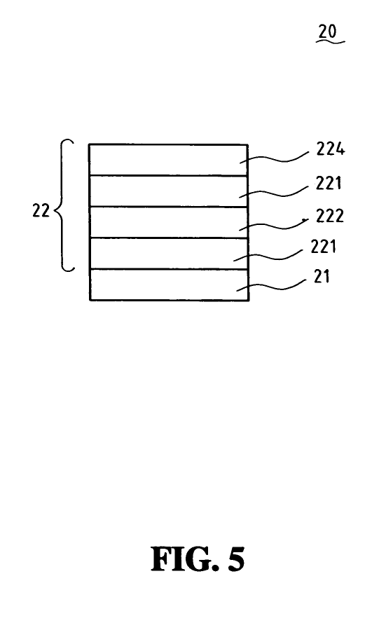

FIGS. 2-5 illustrate a buffer layer 20 within a light emitting semiconducting device according to embodiments of the present invention. As shown in these drawings, an Aluminum nitride layer 21 is first formed on top of a sapphire substrate (not shown in the diagrams) by a nitridation reaction between ammonia (NH₃) and Aluminum molecules of the sapphire substrate under a high temperature. Then on top of the Aluminum nitride layer, a plurality of metallic nitride layers is formed by reactions between ammonia and metallic organic materials under a high temperature. As shown in FIG. 2, the plurality of metallic nitride layers could comprise an Indium nitride (InN) layer 221, an Indium Gallium nitride (InGaN) layer 222, an Aluminum Gallium nitride (AlGaN) layer 223 and a Gallium nitride (GaN) layer 224, sequentially stacked from bottom to top. Or as shown in FIG. 3, another stacking sequence could be, from bottom to top, an Indium nitride (InN) layer 221, an Indium Gallium nitride (InGaN) layer 222, an Indium nitride (InN) layer 221, an Aluminum Gallium nitride (AlGaN) layer 223 and a Gallium nitride (GaN) layer 224. Or, as shown in FIG. 4, another possible stacking sequence could be, from bottom to top, an Indium nitride (InN) layer 221, an Indium Gallium nitride (InGaN) layer 222 and a Gallium nitride (GaN) layer 224. Or as shown in FIG. 5, a stacking sequence could be, from bottom to top, an Indium nitride (InN) layer 221, an Indium Gallium nitride (InGaN) layer 222, an Indium nitride (InN) layer 221 and a Gallium nitride (GaN) layer 224. These stacking sequences are exemplary and explanatory, and are not intended to provide any restriction to the present invention as claimed.

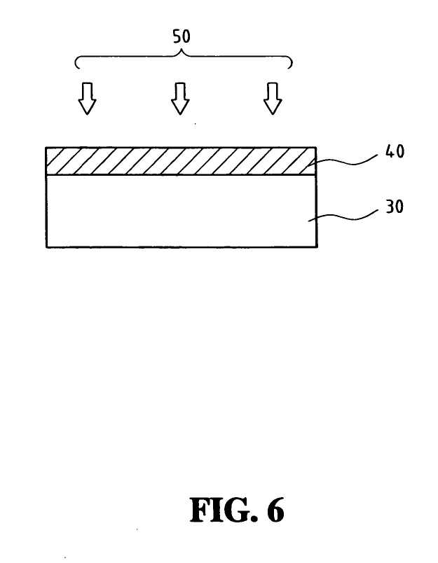

FIG. 6 is a schematic diagram showing, with a light emitting semiconducting device, an Aluminum nitride (AlN) layer 40 of a buffer layer according to the present invention is formed on top of a sapphire substrate 30. The Aluminum nitride (AlN) layer 40 is formed by applying ammonia 50 on the sapphire substrate 30 under a high temperature to trigger a nitridation reaction between the ammonia and Aluminum molecules of the sapphire substrate. The nitridation reaction can be described by a chemical equation as follows:
2Al₂O₃+4NH3->4AlN+6H₂+3O₂

A high quality buffer layer with fewer defects and a smooth surface can be achieved if fabricated according to the present invention. The buffer layer can help improving a light emitting efficiency of a light emitting semiconducting device.

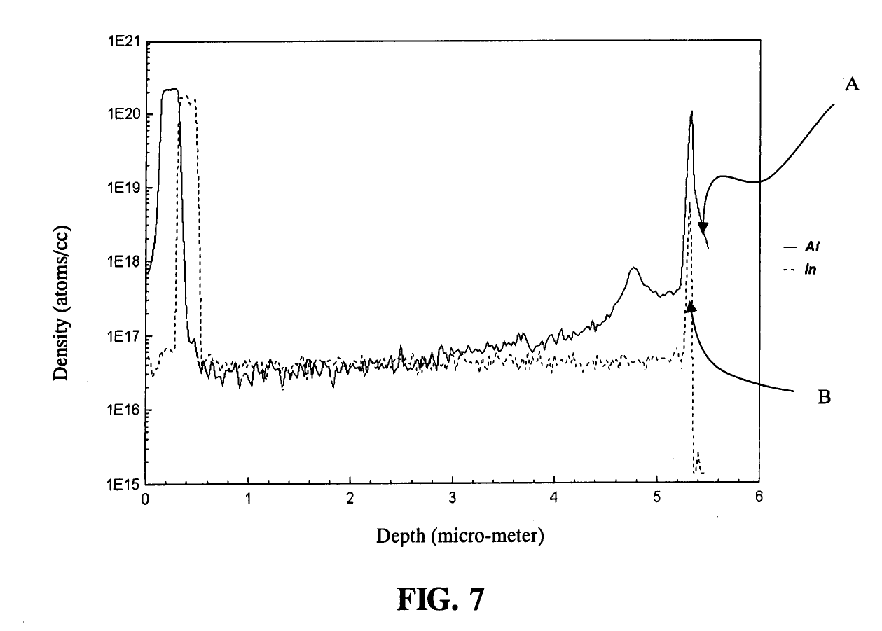

FIG. 7 is an analytical graph showing data obtained from an analysis of a light emitting semiconducting device with a buffer layer according to the present invention under a Secondary Ion Mass Spectrometer (SIMS). As shown in FIG. 7, curves A (solid line) and B (phantom line) represent Aluminum (Al) and Indium (In) respectively. At a depth where a buffer layer would reside, there is indeed Aluminum (Al) and Indium (In) constituents and the densities are 1E+20 atoms/cc and 6E+18 atoms/cc respectively This graph clearly indicates that a buffer layer according to the present invention can indeed be fabricated.

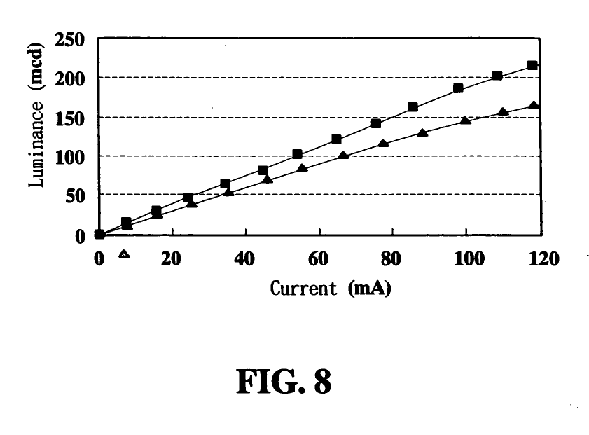

FIG. 8 is a luminance-current characteristics graph showing data obtained from testing a light emitting semiconducting device with a Gallium nitride monocrystalline buffer layer according to a prior art and a light emitting semiconducting device whose buffer layer comprises a plurality of metallic nitride layers according to an embodiment of the present invention as shown in FIG. 2. As FIG. 8 shows, at a same current level, a light emitting semiconducting device according to the present invention has a better luminance than a light emitting semiconducting device according to a prior art.

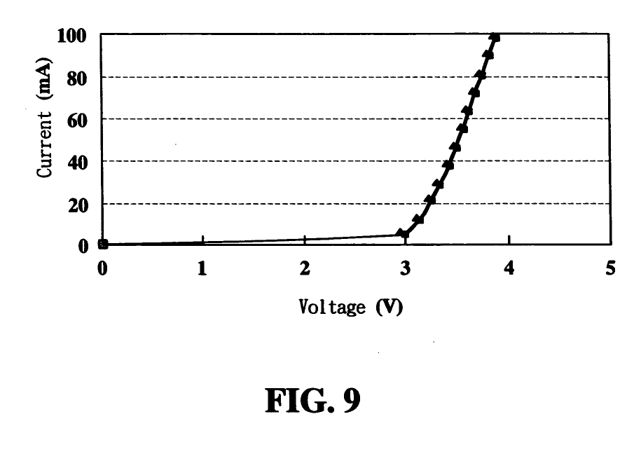

FIG. 9 is a current-voltage characteristics graph showing data obtained from testing a light emitting semiconducting device with a Gallium nitride monocrystalline buffer layer according to a prior art and a light emitting semiconducting device whose buffer layer comprises a plurality of metallic nitride layers according to an embodiment of the present invention as shown in FIG. 2. As FIG. 9 shows, at a same current level, a light emitting semiconducting device according to the present invention requires a lower voltage level than a light emitting semiconducting device according to a prior art.

Based on the foregoing description, a light emitting semiconducting device according to the present invention indeed has a higher light emitting efficiency and a lower operating voltage.

1. A buffer layer within a light emitting semiconducting device, wherein the light emitting semiconducting device comprises a substrate, the buffer layer formed on the substrate, a semiconducting layer for light emission formed on the buffer layer and electrodes for applying external voltages, and wherein the buffer layer comprises:
an Aluminum nitride layer formed on the substrate by a nitridation reaction between ammonia and the substrate's surface under a high temperature; and
a plurality of metallic nitride layers wherein the metallic nitride layers are grown on the Aluminum nitride layer by reactions between ammonia and metallic organic materials under a high temperature.

2. The buffer layer as claimed in claim 1, wherein the plurality of metallic nitride layers is formed by sequentially stacking from bottom to top at least an Indium nitride layer; an Indium Gallium nitride layer, and a Gallium nitride layer.

3. The buffer layer as claimed in claim 2, wherein the plurality of metallic nitride layers may further comprise an Aluminum Gallium nitride layer between the Indium Gallium nitride layer and the Gallium nitride layer.

4. The buffer layer as claimed in claim 3, wherein the plurality of metallic nitride layers may further comprise an Indium nitride layer between the Aluminum Gallium nitride layer and the Indium Gallium nitride layer.

5. The buffer layer as claimed in claim 2, wherein the plurality of metallic nitride layers may further comprise an Indium nitride layer between the Indium Gallium nitride layer and the Gallium nitride layer.

6. The buffer layer as claimed in claim 2, wherein the Indium nitride layer has a thickness between 0.1-50 nm.

7. The buffer layer as claimed in claim 2, wherein the Indium Gallium nitride is made of a material InₓGa₁₋ₓN, wherein 0≦x≦1.

8. The buffer layer as claimed in claim 7, wherein the Indium Gallium nitride layer has a thickness between 0.1-50 nm.

9. The buffer layer as claimed in claim 2, wherein the Gallium nitride layer has a thickness between 0.1-50 nm.

10. The buffer layer as claimed in claim 3, wherein the Aluminum Gallium nitride layer is made of a material Al_{y}Ga_{1-y}N, wherein 0≦y≦1.

11. The buffer layer as claimed in claim 10, wherein the Aluminum Gallium nitride layer has a thickness between 0.1-50 nm.

12. The buffer layer as claimed in claim 4, wherein the Indium nitride layer has a thickness between 0.1-50 nm.

13. The buffer layer as claimed in claim 5, wherein the Indium nitride layer has a thickness between 0.1-50 nm.
